(19) United States
(12) Patent Application Publication
(10) Pub. No.: US 2025/0214457 A1
(43) Pub. Date: Jul. 3, 2025

(54) CONTAINER TRANSPORT APPARATUS AND LOGISTICS HANDLING SYSTEM INCLUDING THE SAME

(71) Applicant: SEMES CO., LTD., Cheonan-si (KR)

(72) Inventors: Geochul JEONG, Gyeonggi-do (KR); Byung Kwon LEE, Gyeonggi-do (KR); Sik KIM, Gyeonggi-do (KR); Yeong Jae CHOE, Gyeonggi-do (KR); Eun Ji CHOI, Gyeonggi-do (KR)

(73) Assignee: SEMES CO., LTD., Cheonan-si (KR)

(21) Appl. No.: 18/780,874

(22) Filed: Jul. 23, 2024

(30) Foreign Application Priority Data
Dec. 29, 2023 (KR) 10-2023-0196142

(51) Int. Cl. B60L 53/12; B65G 1/04

(52) U.S. Cl. CPC B60L 53/12; B65G 1/0457; B65G 1/0492; B60L 2200/26; B60L 2200/36; B65G 2201/0297

(57) ABSTRACT

A container transport apparatus capable of receiving power from batteries and charging the batteries while traveling along rails and a logistics handling system including the container transport apparatus are provided. The logistics handling system is installed in a semiconductor manufacturing plant and includes: a first container transport apparatus transporting a first container where a plurality of substrates are received; a container storage apparatus storing the first container; and a control apparatus controlling the travel of the first container transport apparatus, wherein the first container transport apparatus includes batteries and charges the batteries while traveling along rails.

### CROSS-REFERENCE TO RELATED APPLICATION

This application claims priority from Korean Patent Application No. 10-2023-0196142 filed on Dec. 29, 2023 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a container transport apparatus installed in a semiconductor fabrication plant and a logistics handling system including the same.

### 2. Description of the Related Art

An overhead Hoist Transport (OHT) transports front opening unified pods (FOUPs) to where substrate processing devices are located within a semiconductor manufacturing plant. The OHT accommodates multiple wafers therein.

The OHT operates on electricity supplied through power cables. However, various equipment is installed within the semiconductor manufacturing plant, and there are areas where power cables are not laid out. If the substrate processing devices are located in these areas, it becomes inconvenient as the FOUPs need to be transported by means other than the OHT.

### SUMMARY

Aspects of the present disclosure provide a container transport apparatus that receives power from batteries and charges the batteries while traveling along rails, and a logistics handling system including the container transport apparatus.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a logistics handling system is installed in a semiconductor manufacturing plant and includes: a first container transport apparatus transporting a first container where a plurality of substrates are received; a container storage apparatus storing the first container; and a control apparatus controlling the travel of the first container transport apparatus, wherein the first container transport apparatus includes batteries and charges the batteries while traveling along rails.

According to another aspect of the present disclosure, a container transport apparatus is installed in a semiconductor manufacturing plant, transports a first container where a plurality of substrates are received, and includes: a gripping module gripping the first container; a lifting module lifting up or down the gripping module when gripping the first container; a power supply section providing power; and a drive module connected to drive wheels, which are positioned at either side, and providing a drive force generated with the power to the drive wheels, wherein the power supply section includes a first power supply unit, which is connected to power cables installed in the semiconductor manufacturing plant, a second power supply unit, which includes a plurality of batteries, and a power charger unit, which charges the plurality of batteries, and the power charger unit charges the plurality of batteries when the container transport apparatus travels along rails installed in the semiconductor manufacturing plant.

According to another aspect of the present disclosure, a logistics handling system is installed in a semiconductor manufacturing plant and includes: a container transport apparatus traveling along rails and transporting a first container where a plurality of substrates are received; a container storage apparatus storing the first container; and a control apparatus controlling the travel of the container transport apparatus, wherein the container transport apparatus includes a first power supply unit, which is connected to power cables installed in the semiconductor manufacturing plant and provides power necessary for an operation of the container transport apparatus, a second power supply unit, which includes a plurality of batteries and provides power necessary for an operation of the container transport apparatus, and a power charger unit, which charges the plurality of batteries, the rails include a magnetic flux generator, which generates magnetic flux using a plurality of magnets, the power charger unit includes a voltage generator, which generates voltage using coils, and the power charger unit charges the plurality of batteries using voltage generated when magnetic flux, produced by the plurality of magnets, intersects the coils.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a schematic view illustrating the internal configuration of a logistics handling system according to an embodiment of the present disclosure;

FIG. 2 is a schematic view illustrating the structure of a container transport apparatus that forms the logistics handling system according to an embodiment of the present disclosure;

FIG. 3 is a schematic view illustrating an exemplary installation configuration of the container transport apparatus of FIG. 2 within a semiconductor manufacturing plant;

FIG. 4 is a schematic view for explaining a power supply section within a container transport apparatus according to a first exemplary embodiment of the present disclosure;

FIG. 5 is a first schematic view for explaining a power charger that forms the power supply section of FIG. 4;

FIG. 6 is a second schematic view for explaining the power charger that forms the power supply section of FIG. 4;

FIG. 7 is a schematic view for explaining a voltage generator that forms the power supply section of FIG. 4; and

FIG. 8 is a schematic view for explaining a power supply section within a container transport apparatus according to a second exemplary embodiment of the present disclosure.

### DETAILED DESCRIPTION

Embodiments of the present disclosure will hereinafter be described in detail with reference to the accompanying drawings. The same reference numerals are used for the same components in the drawings, and redundant descriptions thereof will be omitted.

The present disclosure relates to a container transport apparatus and a logistics handling system including the same. The container transport apparatus receives power from batteries and travels along rails to transport containers while being able to charge the battery. The logistics handling system including the container transport apparatus will hereinafter be described first, followed by a description of the container transport apparatus that is operable using batteries.

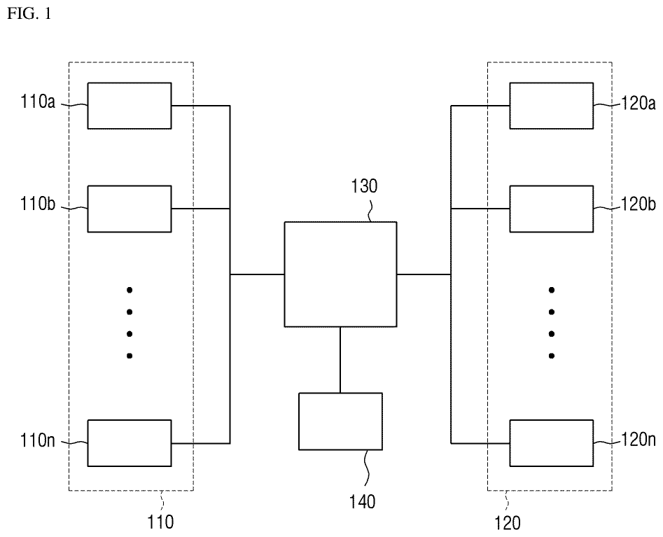

FIG. 1 is a schematic view illustrating the internal configuration of a logistics handling system according to an embodiment of the present disclosure. Referring to FIG. 1, a logistics handling system 100 may be configured to include container transport apparatuses 110, container storage apparatuses 120, a control apparatus 130, and a database 140.

The logistics handling system 100 may be installed within a semiconductor manufacturing plant. The logistics handling system 100 may include a plurality of container transport apparatuses 110 and a plurality of container storage apparatuses 120. The logistics handling system 100 may be constructed to provide automated logistics services within the semiconductor manufacturing plant.

A first direction D1 and a second direction D2 form a horizontal plane. For example, the first direction D1 may be a front-rear direction, and the second direction D2 may be a left-right direction. Alternatively, the first direction D1 may be the left-right direction, and the second direction D2 may be the front-rear direction. A third direction D3 is a vertical direction and is perpendicular to the plane formed by the first and second directions D1 and D2. The third direction D3 may be a top-down direction.

The container transport apparatuses 110 transport containers to their destination. For example, the container transport apparatuses 110 may be provided as overhead hoist transports (OHTs).

The container transport apparatuses 110 may travelling on a travel path (e.g., rails (330a and 330b)) installed on the ceiling of the semiconductor manufacturing plant to transport containers to their destination. The container transport apparatus 110 may transport containers to various process chambers, for example, a deposition process chamber, an etching process chamber, a cleaning process chamber, a heat treatment process chamber, etc., where semiconductor manufacturing processes are performed, and a plurality of container apparatuses 110a, 110b, . . . , 110n may be arranged within the semiconductor manufacturing plant. When the container transport apparatuses 110 transport containers to equipment

where semiconductor manufacturing processes are performed, each of the containers may accommodate a plurality of substrates (e.g., wafers). The containers may be provided as front opening unified pods (FOUPs).

The container transport apparatuses 110 may operate under the control of the control apparatus 130. To this end, although not illustrated in FIG. 1, each of the container transport apparatuses 110 may include a communication module for wired/wireless communication with the control apparatus 130.

The container transport apparatuses 110 may also be able to operate autonomously without the control of the control apparatus 130. In this case, numerous sensors may be installed around the travel path of the container transport apparatuses 110 to provide information to prevent collisions between the container transport apparatuses 110a, 110b, . . . , 110n within the semiconductor manufacturing plant, and the container transport apparatuses 110a, 110b, . . . , 110n may also be configured to be able to communicate with one another.

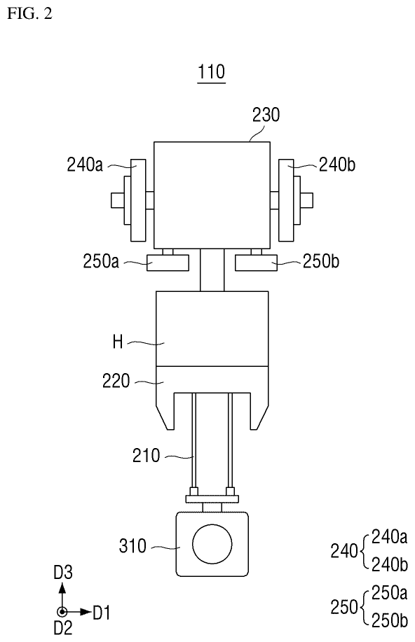

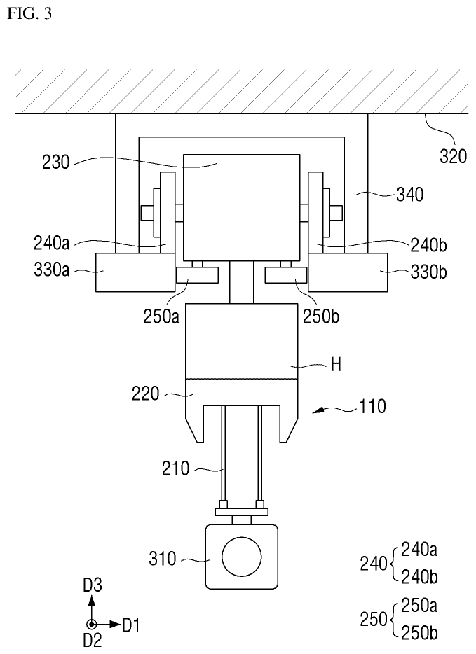

FIG. 2 is a schematic view illustrating the structure of a container transport apparatus that forms the logistics handling system according to an embodiment of the present disclosure. FIG. 3 is a schematic diagram illustrating the installation configuration of the container transport apparatus of FIG. 2 within a semiconductor manufacturing plant. Referring to FIGS. 2 and 3, a container transport apparatus 110 may be configured to include a gripping module 210, a lifting module 220, a driving module 230, driving wheels 240, and guide wheels 250.

The gripping module 210 is provided to grip a container 310. The gripping module 210 may descend to a location (e.g., an equipment front end module (EFEM)) where the container 310 is placed to grip the container 310 and transport the container 310 to its destination. The gripping module 210 may be provided as, for example, a hand gripper.

The lifting module 220 is provided to lift up or down the gripping module 210. The lifting module 220 may lift down the gripping module 210 in a direction where the ground is located from near a ceiling 320 to enable the gripping module 210 to grip the container 310, and once the gripping module 210 grips the container 310, the lifting module 220 may lift the gripping module 210 back up near the ceiling 320. The lifting module 220 may be provided as, for example, a hoist.

Once the container 310 is loaded by the gripping module 210 and the lifting module 220, the container transport apparatus 110 may transport the container 310 to its destination. When the container transport apparatus 110 reaches the destination, the lifting module 220 lifts down the gripping module 210 again, and the gripping module 210 releases its grip on the container 310 mounted on the load port module of the EFEM, allowing the substrates stored in the container 310 to be transferred to process equipment where a subsequent semiconductor manufacturing process is to be performed.

Meanwhile, although not illustrated in FIGS. 2 and 3, the container transport apparatus 110 may also include a storage module, which provides an accommodation space, instead of the gripping module 210. The storage module may be formed in a shape (e.g., a basket shape) with an open top to accommodate the container 310, and may also be formed in a shape (e.g., a cabinet shape) with a side door that can be opened and closed.

The driving module 230 controls the driving wheels 240, which travel along the travel path (for example, a pair of rails 330a and 330b) installed on the ceiling 320 of the semiconductor manufacturing plant. Although not illustrated in FIGS. 2 and 3, the driving module 230 may include a driving motor, a drive shaft, etc., for this purpose. Here, the driving motor may generate a driving force, and the drive shaft may provide the driving force generated by the driving motor to the driving wheels 240.

The driving wheels 240 are rotators that use the driving force provided by the driving module 230 to rotate, allowing the container transport apparatus 110 to travel on the pair of rails 330a and 330b. The driving wheels 240 may be provided as a pair of driving wheels 240a and 240b to be able to travel on the pair of rails 330a and 330b, respectively, in which case, the driving wheels 240a and 240b may be coupled to either side of the driving module 230.

The guide wheels 250 prevent the container transport apparatus 110 from deviating from the pair of rails 330a and 330b when the container transport apparatus 110 travels on the pair of rails 330a and 330b. Similarly to the driving wheels 240, the guide wheels 250 may be provided in a pair of guide wheels 250a and 250b and may be installed at either end of the bottom surface of the driving module 230 to be perpendicular to the driving wheels 240a and 240b, respectively.

The container transport apparatus 110 may include a speed control section, a position control section, etc. Here, the speed control section may control the rotation speed of the driving wheels 240, and the position control section may correct the position of the container 310.

The position control section may include a slider and a rotator. The slider may move the container 310 in the top-bottom direction or the left-right direction, and the rotator may rotate the container 310 clockwise or counterclockwise.

To provide a travel path for the container transport apparatus 110, a rail assembly, which includes the pair of rails 330a and 330b and a rail support module 340, may be installed on the ceiling 320 of the semiconductor manufacturing plant. As previously described, the pair of rails 330a and 330b provide a travel path for the container transport apparatus 110 and may be coupled to either end of the rail support module 340, which is fixed to the ceiling 320 of the semiconductor manufacturing plant.

The pair of rails 330a and 330b may be configured to include various types of sections, such as a straight section, a curved section, an inclined section, a branching section, and an intersection, depending on the layout of the ceiling 320 within the semiconductor manufacturing plant, but the present disclosure is not limited thereto. The pair of rails 330a and 330b may also be configured to include only one type of section among the various types of sections.

The rail support module 340 is fixed to the ceiling 320 of the semiconductor manufacturing plant and supports the pair of rails 330a and 330b. The rail support module 340 may be installed on the ceiling 320 of the semiconductor manufacturing plant to have a cap shape when viewed from the ground.

Referring back to FIG. 1, the container storage apparatuses 120 may store containers 310. For this purpose, each of the container storage apparatuses 120 may include an internal storage module. The storage module may be configured to be multi-tiered. At least one container 310 may be stored at each tier of the storage module, allowing the storage module to store a plurality of containers 310. The storage module may be configured to be multi-tiered in the third direction D3, but the present disclosure is not limited thereto. Alternatively, the storage module may be configured to be multi-tiered in the first direction D1 or the second direction D2. Yet alternatively, the storage module may be configured to be multi-tiered in one of the first and second directions D1 and D2 and the third direction D3. The container storage apparatuses 120, like the container transport apparatuses 110, may be provided as a plurality of storage units 120a, 120b, . . . , 120n.

The container storage apparatuses 120 may be installed in the interior space of the semiconductor manufacturing plant. The container storage apparatuses 120 may be installed on the floor of the semiconductor manufacturing plant. The container storage apparatuses 120 may be stockers. The container storage apparatuses 120 may also be installed on the ceiling of the semiconductor manufacturing plant. The container storage apparatuses 120 may be side-track buffers (STBs).

The control apparatus 130 controls the container transport apparatuses 110a, 110b, 110n. The control apparatus 130 may independently control each of the container transport apparatuses 110a, 110b, . . . , 110n to safely transport containers 310 to their destination (e.g., various process equipment where semiconductor manufacturing processes are to be performed).

The control apparatus 130 may control the travel of the container transport apparatuses 110 by transmitting signals such as a start command, a stop command, an acceleration command, a deceleration command, etc., to the container transport apparatuses 110. Moreover, the control apparatus 130 may provide necessary information (e.g., a route to the destination) to the container transport apparatuses 110 through wired/wireless communication with the container transport apparatuses 110.

The control apparatus 130 may recognize the position of each of the container transport apparatuses 110a, 110b, . . . , 110n. In this case, the control apparatus 130 may use a plurality of sensors installed around the rails (330a and 330b) and may also use result data obtained through wired/wireless communication with each of the container transport apparatuses 110a, 110b, . . . , 110n.

In the former case, the control apparatus 130 may recognize the position of each of the container transport apparatuses 110a, 110b, . . . , 110n by using information such as identification information of each sensor (e.g., Serial Number), location information of each sensor (e.g., two-dimensional (2D) coordinate information (x, y) or three-dimensional (3D) coordinate information (x, y, z)), and identification information of each of the container storage apparatuses 120 that has passed through each sensor. In the latter case, each of the container transport apparatuses 110a, 110b, . . . , 110n may independently measure its own position, and the control apparatus 130 may recognize the position of each of the container transport apparatuses 110a, 110b, . . . , 110n through communication with each of the container transport apparatuses 110a, 110b, . . . , 110n.

The control apparatus 130 may include a processor that executes control over each of the components of the logistics handling system 100, a network that communicates with each of the components of the logistics handling system 100 in a wired or wireless manner, one or more instructions related to the functions or operations to control each of the components of the logistics handling system 100, storage means for storing processing recipes including instructions and various data, etc. The control apparatus 130 may further include a user interface, which includes input means for an operator to perform command input manipulations to manage the logistics handling system 100 and output means to visualize and display the operational status of the logistics handling system 100. The control apparatus 130 may be provided as a computing device for data processing and analysis, command transmission, etc.

The instructions may be provided in the form of a computer program or application. A computer program may include one or more instructions and may be stored on a computer-readable recording medium. The instructions may include code generated by a compiler, code executable by an interpreter, etc. The storage means may be provided as one or more storage media selected from among a flash memory, a hard disk drive (HDD), a solid-state drive (SSD), a card-type memory, a random-access memory (RAM), a static RAM (SRAM), a read-only memory (ROM), an electrically erasable programmable ROM (EEPROM), a programmable ROM (PROM), a magnetic memory, a magnetic disk, and an optical disk.

The database 140 stores information necessary for the control apparatus 130 to control the container transport apparatuses 110a, 110b, . . . , 110n. The database 140 may be embedded within the control apparatus 130 or may be separately provided externally and connected in a wired or wireless manner to provide necessary information to the control apparatus 130.

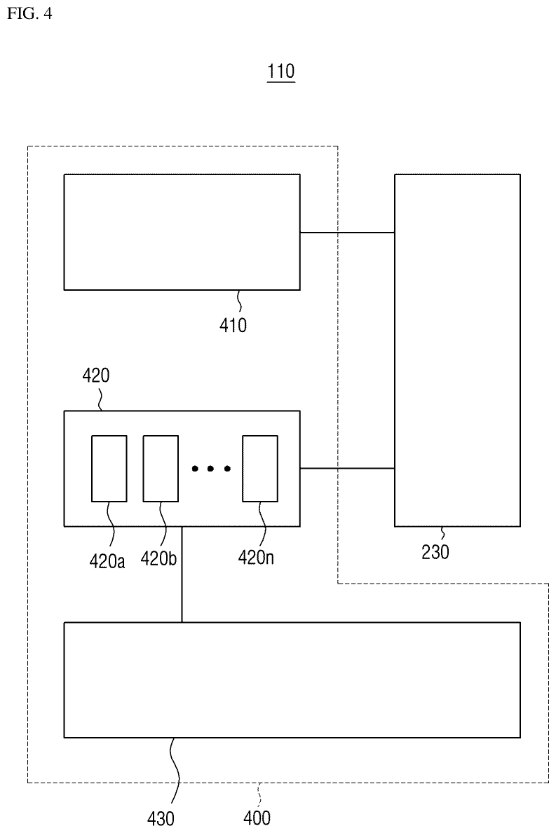

A container transport apparatus 110 that operates using batteries will hereinafter be described. FIG. 4 is a schematic view for explaining a power supply section within a container transport apparatus according to a first exemplary embodiment of the present disclosure.

Referring to FIG. 4, a power supply section 400 of the container transport apparatus 110 may include a first power supply unit 410, a second power supply unit 420, and a power charger unit 430.

The first power supply unit 410 may be connected to power cables installed within a semiconductor manufacturing plant. The first power supply unit 410 may supply the power provided through the power cables to components within the container transport apparatus 110 that need power. For example, the first power supply unit 410 may supply the power provided through the power cables to a driving module 230. The first power supply unit 410 may supply power to the driving motor within the driving module 230.

The first power supply unit 410 may receive alternating current (AC) power through the power cables. The first power supply unit 410 may supply power to a driving motor that operates using direct current (DC) power. The first power supply unit 410 may include an AC/DC converter. The first power supply unit 410 may convert AC power into DC power through the AC/DC converter and then supply the DC power to the driving motor.

The first power supply unit 410 may receive DC power through the power cables. The first power supply unit 410 may supply power to a driving motor that operates using AC power. The first power supply unit 410 may include a DC/AC converter. The first power supply unit 410 may convert DC power into AC power through the DC/AC converter and then supply the AC power to the driving motor.

If the first power supply unit 410 receives AC power and supplies the received AC power to a driving motor that operates using AC power, the first power supply unit 410 may not include an AC/DC converter or a DC/AC converter. Similarly, if the first power supply unit 410 receives DC power and supplies the received DC power to a driving motor that operates using DC power, the first power supply unit 410 may also not include an AC/DC converter or a DC/AC converter.

The second power supply unit 420 does not receive power from an external source but may have power stored in advance. The second power supply unit 420 may include one or more batteries 420a, 420b, . . . , 420n.

The second power supply unit 420 may provide the power stored in the batteries 420a, 420b, . . . , 420n to the components within the container transport apparatus 110 that require power in case of an emergency. For example, the second power supply unit 420 may supply power to the driving module 230. If the first power supply unit 410 is unable to supply power to the driving module 230, the second power supply unit 420 may provide the power stored in the batteries 420a, 420b, . . . , 420n to the driving module 230.

The power charger unit 430 is capable of charging the batteries 420a, 420b, . . . , 420n. The power charger unit 430 may charge the batteries 420a, 420b, . . . , 420n when their state of charge (SoC) falls below a reference level. For example, the power charger unit 430 may initiate charging of the batteries 420a, 420b, . . . , 420n when their charge level drops below 20%.

The second power supply unit 420 may include the batteries 420a, 420b, . . . , 420n. The power charger unit 430 may start charging the batteries 420a, 420b, . . . 420n if the charge level of any one of the batteries 420a, 420b, . . . , 420n falls below the reference level. Alternatively, the power charger unit 430 may start charging the batteries 420a, 420b, . . . , 420n only when the charge levels of the batteries 420a, 420b, . . . , 420n are all below the reference level.

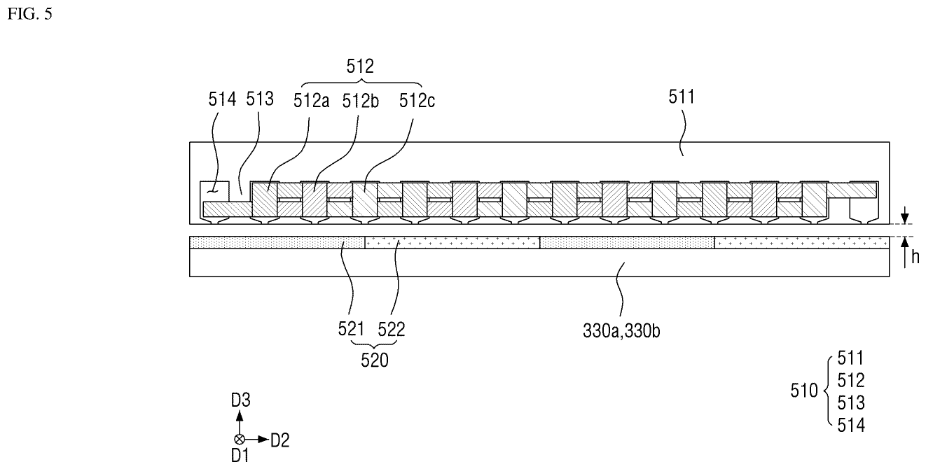

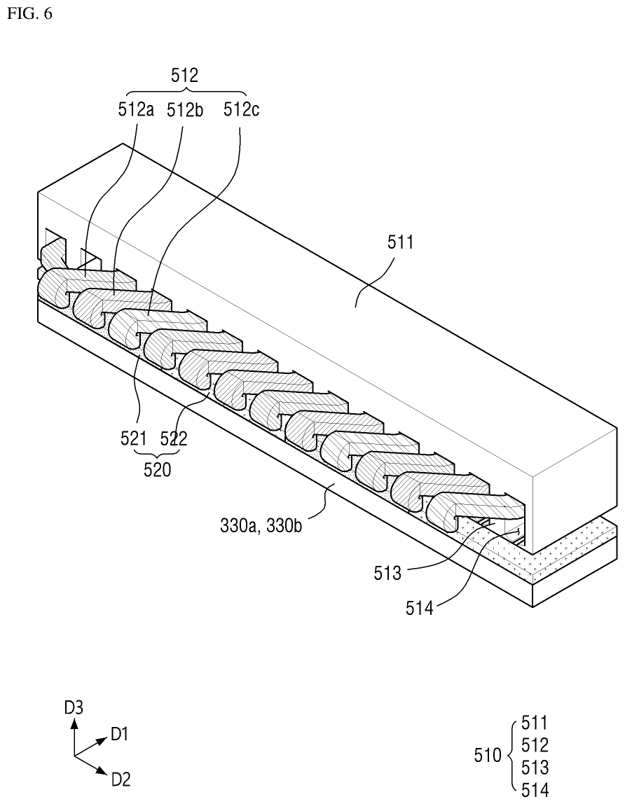

The power charger unit 430 may charge the batteries 420a, 420b, . . . , 420n while the container transport apparatus 110 travels along the rails (330a and 330b) for transporting containers 310. FIG. 5 is a first exemplary schematic view for explaining a power charger that forms the power supply section of FIG. 4. FIG. 6 is a second exemplary schematic view for explaining the power charger that forms the power supply section of FIG. 4.

The power charger unit 430 includes a voltage generator 510, and a magnetic flux generator 520 may be installed in the rails (330a and 330b). The voltage generator 510 may be installed within the container transport apparatus 110. The voltage generator 510 may be installed adjacent to the rails (330a and 330b).

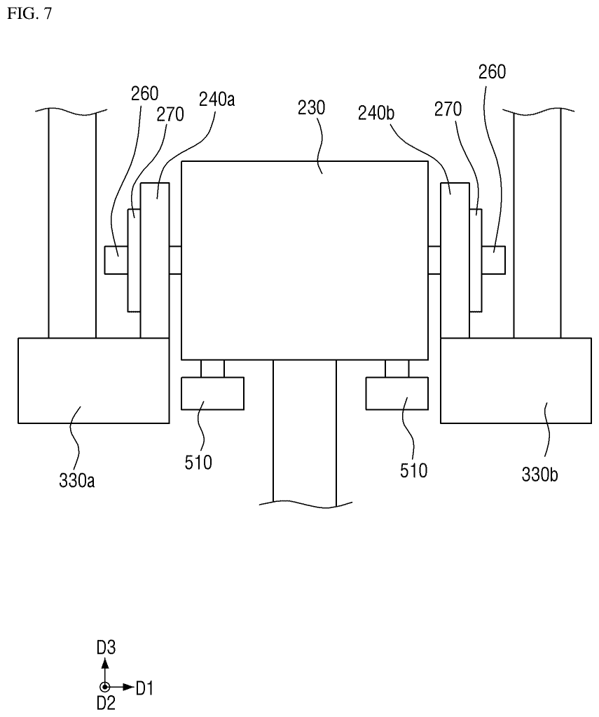

Referring to FIG. 7, the voltage generator 510 may be adjacent to the rails (330a and 330b) from the bottom of the driving module 230. The voltage generator 510 may be provided at the location where the guide wheels 250a and 250b are installed. In this case, the voltage generator 510 may be provided not to contact the rails (330a and 330b). If the voltage generator 510 includes 3-phase coils, U-phase coils, W-phase coils, and V-phase coils may be installed in parallel to the lengthwise direction of the rails (330a and 330b). The container transport apparatus 110 may not include the guide wheels 250a and 250b.

However, the present disclosure is not limited to this, and alternatively, the voltage generator 510 may be provided on the drive shaft 260. In this case, the 3-phase coils (i.e., the U-phase coils, the W-phase coils, and the V-phase coils) may be sequentially and repetitively arranged along the rotation direction of the drive shaft 260. Yet alternatively, the voltage generator 510 may be provided on fixing members 270 that bind the driving wheels 240a and 240b to the drive shaft 260. In this case, the 3-phase coils (i.e., the U-phase coils, the W-phase coils, and the V-phase coils) may be sequentially and repetitively arranged along the rotation direction of the fixing members 270. Still alternatively, the voltage generator 510 may be provided within the driving wheels 240a and 240b. In this case, the 3-phase coils (i.e., the U-phase coils, the W-phase coils, and the V-phase coils) may be sequentially and repetitively arranged along the rotation direction of the driving wheels 240a and 240b. FIG. 7 is a schematic view for explaining the voltage generators that form the power supply section according to the first exemplary embodiment of the present disclosure.

Referring back to FIGS. 5 and 6, each of the voltage generator 510 may include a main body 511 and coils 512. The main body 511 may include a plurality of protrusions 513. The protrusions 513 may be arranged along the lengthwise direction of the rails (330a and 330b), i.e., along the second direction D2. Slots 514 may be formed between the protrusions 513. The coils 512 can be formed through the protrusions 513. The coils 512 may be provided as 3-phase coils, including U-phase coils 512a, V-phase coils 512b, and W-phase coils 512c, but the present disclosure is not limited thereto. The U-phase coils 512a, the V-phase coils 512b, and the W-phase coils 512c may be formed repeatedly along the lengthwise direction (D2) of the rails (330a and 330b). The coils 512 may be wound in a concentrated winding manner, but the present disclosure is not limited thereto. Alternatively, the coils 512 may be wound in a distributed winding manner. Yet alternatively, the coils 512 may be wound in a full-pitch winding or a fractional-pitch winding manner.

The magnetic flux generator 520 may be installed on the rails (330a and 330b). A predetermined distance h may be formed between the voltage generator 510 of the container transport apparatus 110 and the magnetic flux generator 520 on the rails (330a and 330b). The magnetic flux generator 520 may include a plurality of magnets (521 and 522). The magnets (521 and 522) may include magnets 521 with a first polarity and magnets 522 with a second polarity. The magnets 521 may be magnets with one of N-pole polarity and S-pole polarity. The magnets 522 may be magnets of the other one of the N-pole polarity and the S-pole polarity. There may be a plurality of magnets 521. Similarly, there may be a plurality of magnets. The magnets 521 and the magnets 522 are alternately formed and may be repetitively formed along the lengthwise direction (D2) of the rails (330a and 330b). The magnets 521 and the magnets 522 may both be provided as permanent magnets, but the present disclosure is not limited thereto. Alternatively, the magnets 521 with the first polarity and the magnets 522 with the second polarity may both be provided as electromagnets. Yet alternatively, the magnets 521 and the magnets 522 may be provided as permanent magnets and electromagnets, respectively, or vice versa.

The magnetic flux generator 520 may be installed in all the areas within the semiconductor manufacturing plant where the rails (330a and 330b) are installed. In other words, the magnetic flux generator 520 may be installed in all the rails (330a and 330b) within the semiconductor manufacturing plant, but the present disclosure is not limited thereto. Alternatively, the magnetic flux generator 520 may be installed in only some of the rails (330a and 330b) within the semiconductor manufacturing plant. For example, the magnetic flux generator 520 may be installed in areas in the semiconductor manufacturing plant where the power cables are not laid out.

Alternatively, the magnetic flux generator 520 may be installed in areas in the semiconductor manufacturing plant that have relatively high traffic. The semiconductor manufacturing plant may include a plurality of container transport apparatuses 110. The container transport apparatuses 110 may include container transport apparatuses (i.e., wafer transport apparatuses) that transport containers carrying a plurality of wafers and container transport apparatuses (i.e., reticle transport apparatuses) that transport containers carrying a plurality of reticles. In some areas within the semiconductor manufacturing plant, the wafer transport apparatuses and the reticle transport apparatuses may both be used. These areas may be reticle zones, and the reticle zones may have higher traffic compared to other zones. In such high-traffic areas, the power consumption of the container transport apparatuses may be relatively high, and the power cables connected to the container transport apparatuses may get tangled. By installing the magnetic flux generator 520 in the rails (330a and 330b) in the reticle zones, issues associated with the power consumption of the container transport apparatuses and problems such as entanglement of the power cables can be addressed.

When the voltage generator 510 and the magnetic flux generator 520 are installed as described, the magnetic flux generated by the magnets (521 and 522) when the container transport apparatus 110 travels along the rails (330a and 330b) may intersect the coils 512, generating a voltage according to Ampere's Law and Faraday's Law. The power charger unit 430 may charge the batteries 420a, 420b, . . . , 420n with the voltage obtained through the voltage generator 510. The voltage generator 510 and the magnetic flux generator 520 may be provided as a linear generator system capable of charging the batteries 420a, 420b, . . . , 420n. The power charger unit 430 may include a regulator to charge the batteries 420a, 420b, . . . , 420n with the voltage generated in the coils 512. The power charger unit 430 may also include an inverter, a DC/DC converter, etc.

The voltage obtained through the interaction between the voltage generator 510 and the magnetic flux generator 520 may be used to charge the batteries 420a, 420b, . . . , 420n, but the present disclosure is not limited thereto. The voltage obtained through the voltage generator 510 may also be provided to the driving module 230. The power charger unit 430 may provide the voltage obtained through the voltage generator 510 to the driving module 230, instead of using it to charge the batteries 420a, 420b, . . . , 420n. The container transport apparatuses 110 may use the voltage obtained through the voltage generator 510 to travel along the rails (330a and 330b). Alternatively, the voltage obtained through the voltage generator 510 may also be provided to a sensor module. The power charger unit 430 may not use this voltage to charge the batteries 420a, 420b, . . . , 420n but provide it to the sensor module. The container transport apparatus 110 may use this voltage to acquire ambient sensing information. Furthermore, the voltage obtained through the voltage generator 510 may be provided to the communication module. The power charger unit 430 may not use this voltage to charge the batteries 420a, 420b, 420n but provide it to the communication module. The container transport apparatus 110 may use this voltage to communicate with the control apparatus 130.

If the SoC of the batteries 420a, 420b, . . . , 420n is above the reference level, the power charger unit 430 does not charge the batteries 420a, 420b, . . . , 420n, and instead, provides power to the driving module 230, the sensor module, the communication module, etc. For example, if the SoC of the batteries 420a, 420b, . . . , 420n is above 80%, the power charger unit 430 may supply power to the driving module 230, the sensor module, the communication module, etc. The power charger unit 430 may control an inverter to supply power to the driving module 230, the sensor module, the communication module, etc. The power charger unit 430 may control the inverter through various control methods such as position control, speed control, vector control, etc., to supply power to the driving module 230, the sensor module, the communication module, etc.

Alternatively, the power supply section 400 of the container transport apparatus 110 may not include the first power supply unit 410 and may only include the second power supply unit 420 and the power charger unit 430. In this case, the second power supply unit 420 may provide all the power necessary for the operation of the container transport apparatus 110. The power charger unit 430 may charge the batteries 420a, 420b, . . . , 420n in the areas where the power cables are laid out, and the container transport apparatus 110 may rely entirely on the power provided by the batteries 420a, 420b, . . . , 420n in the areas where no power cables are laid out.

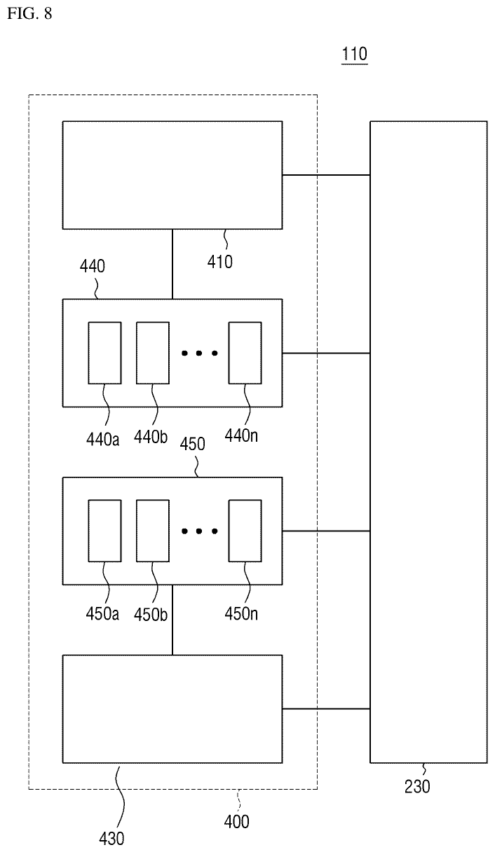

FIG. 8 is a schematic view for explaining a power supply section within a container transport apparatus according to a second exemplary embodiment of the present disclosure. Referring to FIG. 8, a power supply section 400 of a container transport apparatus 110 may include a first power supply unit 410, a third power supply unit 440, a fourth power supply unit 450, and a power charger unit 430.

The embodiment of FIG. 8 will hereinafter be described, omitting the descriptions for the content that overlaps with the embodiment of FIG. 4 and focusing mainly on the differences from the embodiment of FIG. 4. The descriptions for the first power supply unit 410 and the power charger unit 430 of FIGS. 4 through 7 may be directly applicable to the embodiment of FIG. 8.

The second power supply unit 420 of FIG. 4 may be configured to include the third power supply unit 440 and the fourth power supply unit 450 of FIG. 8. Alternatively, the third power supply unit 440 and the fourth power supply unit 450 of FIG. 8 may be provided instead of the second power supply unit 420 of FIG. 4.

The third power supply unit 440 may include one or more main batteries 440a, 440b, . . . , 440n. The fourth power supply unit 450 may include one or more auxiliary batteries 450a, 450b, . . . , 450n.

The main batteries 440a, 440b, . . . , 440n may be charged through the power charger unit 430 using power cables. The auxiliary batteries 450a, 450b, . . . , 450n may be charged through the power charger unit 430 using a voltage generator 510 and a magnetic flux generator 520. The main batteries 440a, 440b, . . . , 440n and the auxiliary batteries 450a, 450b, . . . , 450n may be connected to one another, but the present disclosure is not limited thereto. Alternatively, the main batteries 440a, 440b, . . . , 440n and the auxiliary batteries 450a, 450b, . . . , 450n may not be connected to one another. The main batteries 440a, 440b, . . . , 440n may be charged using the auxiliary batteries 450a, 450b, . . . , 450n if needed. The auxiliary batteries 450a, 450b, . . . , 450n may be charged using the main batteries 440a, 440b, . . . , 440n.

When the container transport apparatus 110 is moving along rails (330a and 330b), the container transport apparatus 110 may use the power stored in the main batteries 440a, 440b, 440n. The container transport apparatus 110 may use the power stored in the main batteries 440a, 440b, . . . , 440n to operate a driving module 230. For information acquisition using sensors, the container transport apparatus 110 may use the power stored in the auxiliary batteries 450a, 450b, . . . , 450n. For communication with a control apparatus 130, the container transport apparatus 110 may use the power stored in the auxiliary batteries 450a, 450b, . . . , 450n.

When the container transport apparatus 110 operates using batteries 420a, 420b, . . . , 420n in areas where power cables are not laid out, the SoC of the batteries 420a, 420b, . . . , 420n may decrease. However, according to embodiments of the present disclosure, the batteries 420a, 420b, . . . , 420n can be charged even in the areas without the power cables through a linear generation system. If the SoC of the batteries 420a, 420b, . . . , 420n is above the reference level, drive power can be provided to the container transport apparatus 110 without charging the batteries 420a, 420b, . . . , 420n. Moreover, the usage of high intensity discharge (HID) inverters 5 and power cables in the semiconductor manufacturing plant can be further reduced. Additionally, the frequency of the container transport apparatus 110 moving to the areas where the power cables are laid out, solely for charging the batteries 420a, 420b, . . . , 420n, can be reduced, consequently increasing the throughput of operations.

While the embodiments of the invention have been described with reference to the accompanying drawings, it should be understood that the invention is not limited to these embodiments. The invention can be manufactured in various different forms, and those skilled in the art will appreciate that the invention can be implemented in other specific forms without departing from the technical spirit or essential characteristics of the invention. Therefore, the described embodiments should be considered in all respects as illustrative and not restrictive.

What is claimed is:

1. A logistics handling system installed in a semiconductor manufacturing plant, comprising:
a first container transport apparatus transporting a first container where a plurality of substrates are received;
a container storage apparatus storing the first container; and
a control apparatus controlling the travel of the first container transport apparatus,
wherein the first container transport apparatus includes batteries and charges the batteries while traveling along rails.

2. The logistics handling system of claim 1, wherein the first container transport apparatus further includes a second power supply unit, which includes a plurality of batteries and provides power necessary for an operation of the first container transport apparatus, and a power charger unit, which charges the plurality of batteries.

3. The logistics handling system of claim 2, wherein the first container transport apparatus further includes a first power supply unit, which is connected to power cables installed in the semiconductor manufacturing plant and provides power necessary for an operation of the first container transport apparatus.

4. The logistics handling system of claim 3, wherein if the first power supply unit is unable to provide power, the second power supply unit provides power.

5. The logistics handling system of claim 2, wherein the power charger unit includes a voltage generator, which generates voltage using coils, and charges the plurality of batteries using the voltage.

6. The logistics handling system of claim 5, wherein the rails include a magnetic flux generator, which generates magnetic flux using a plurality of magnets.

7. The logistics handling system of claim 6, wherein
the magnetic flux generator includes first magnets and second magnets with a different polarity from the first magnets, and
the first magnets and the second magnets are alternately installed along a lengthwise direction of the rails.

8. The logistics handling system of claim 5, wherein
the voltage generator includes first coils, second coils, and third coils, which generate alternating currents (ACs) with different phases, and
the first coils, the second coils, and the third coils are alternately installed in a direction parallel to a lengthwise direction of the rails.

9. The logistics handling system of claim 5, wherein the voltage generator includes a main body, a plurality of protrusions, which are formed on a surface of the main body and are arranged in one direction to be spaced apart from one another, and coils, which are installed through the protrusions and slots that are formed between the protrusions.

10. The logistics handling system of claim 6, wherein the voltage generator and the magnetic flux generator do not contact each other.

11. The logistics handling system of claim 6, wherein the magnetic flux generator is installed in rails in areas where the first container transport apparatus is not connected to power cables installed in the semiconductor manufacturing plant.

12. The logistics handling system of claim 6, further comprising:
a second container transport apparatus transporting a second container where a plurality of reticles are received,
wherein the magnetic flux generator is installed in rails in areas where the first and second container transport apparatuses are used together.

13. The logistics handling system of claim 5, wherein the power charger unit provides the voltage as power necessary for an operation of the first container transport apparatus.

14. The logistics handling system of claim 13, wherein if a state of charge (SoC) of the plurality of batteries is above a reference level, the power charger unit provides the voltage as power necessary for an operation of the first container transport apparatus.

15. The logistics handling system of claim 2, wherein the second power supply unit includes a third power supply unit, which includes a plurality of main batteries, and a fourth power supply unit, which includes a plurality of auxiliary batteries.

16. The logistics handling system of claim 15, wherein the power charger unit charges the main batteries using power cables installed in the semiconductor manufacturing plant, and charges the auxiliary batteries using voltage obtained while traveling along the rails.

17. The logistics handling system of claim 15, wherein
the third power supply unit provides power stored in the main batteries if the container transport apparatus travels along the rails, and
the fourth power supply unit provides power stored in the auxiliary batteries if the container transport apparatus performs sensing or communication.

18. A container transport apparatus installed in a semiconductor manufacturing plant and transporting a first container where a plurality of substrates are received, comprising:
a gripping module gripping the first container;
a lifting module lifting up or down the gripping module when gripping the first container;
a power supply section providing power; and
a drive module connected to drive wheels, which are positioned at either side, and providing a drive force generated with the power to the drive wheels,
wherein
the power supply section includes a first power supply unit, which is connected to power cables installed in the semiconductor manufacturing plant, a second power supply unit, which includes a plurality of batteries, and a power charger unit, which charges the plurality of batteries, and
the power charger unit charges the plurality of batteries when the container transport apparatus travels along rails installed in the semiconductor manufacturing plant.

19. The container transport apparatus of claim 18, wherein the power charger unit includes coils, and charges the plurality of batteries using voltage generated when magnetic flux, produced by a plurality of magnets installed in the rails, intersects the coils.

20. A logistics handling system installed in a semiconductor manufacturing plant, comprising:
a container transport apparatus traveling along rails and transporting a first container where a plurality of substrates are received;
a container storage apparatus storing the first container; and
a control apparatus controlling the travel of the container transport apparatus,
wherein
the container transport apparatus includes a first power supply unit, which is connected to power cables installed in the semiconductor manufacturing plant and provides power necessary for an operation of the container transport apparatus, a second power supply unit, which includes a plurality of batteries and provides power necessary for an operation of the container transport apparatus, and a power charger unit, which charges the plurality of batteries,
the rails include a magnetic flux generator, which generates magnetic flux using a plurality of magnets,
the power charger unit includes a voltage generator, which generates voltage using coils, and
the power charger unit charges the plurality of batteries using voltage generated when magnetic flux, produced by the plurality of magnets, intersects the coils.
